(19) United States
(12) Patent Application Publication
(10) Pub. No.: US 2026/0150436 A1
(43) Pub. Date: May 28, 2026

(54) RECESSED CAVITY SUBSTRATES FOR LED MATRIX

(71) Applicant: CreeLED, Inc., Durham, NC (US)

(72) Inventors: David Suich, Durham, NC (US); Michael Check, Holly Springs, NC (US); Joseph G. Sokol, Durham, NC (US); Colin Blakely, Raleigh, NC (US)

(21) Appl. No.: 18/960,062

(22) Filed: Nov. 26, 2024

(51) Int. Cl. H01L 33/20; H01L 25/075

(52) U.S. Cl. CPC H10H 20/819; H10W 90/00

(57) ABSTRACT

Light-emitting diode (LED) components, and more particularly, LED components that have substrates with recessed cavities are disclosed for LED matrix applications. LED matrix applications involve an array of LEDs closely spaced together, resulting in conventional applications, an undesired level of crosstalk where light from one LED chip excites the phosphors and/or epitaxial layers on a neighboring LED chip. The present disclosure describes LED components with recessed cavities on a substrate, where the LED chips can be placed in the cavities, enabling the sidewalls of the cavities to prevent cross-talk between the LED chips in the LED matrix. The recessed cavities in the substrate can be used for flip-chip mounted chips or LED chips with vertical geometry. Additionally, an LED matrix can have recesses with varying depths to enable customized emission patterns.

### FIELD OF THE DISCLOSURE

The present disclosure relates to light-emitting diode (LED) components with recessed cavities in a substrate for LED matrices.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new applications, including LED displays and lighting devices for general illumination.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from gallium nitride, gallium phosphide, aluminum nitride, indium nitride, gallium-indium-based materials, gallium arsenide-based materials, and/or from organic semiconductor materials.

LED packages have been developed that can provide mechanical support, electrical connections, and encapsulation for LED emitters. As LED technology continues to be developed for ever-evolving modern applications, challenges exist in keeping up with operating demands for LED packages and related elements of LED packages.

The art continues to seek improved LEDs and solid-state lighting devices having desirable illumination characteristics capable of overcoming challenges associated with conventional lighting devices.

### SUMMARY

The present disclosure relates to light-emitting diode (LED) components, and more particularly to substrates for LED matrices that have recessed cavities. LED matrix applications involve an array of LEDs closely spaced together, resulting in conventional applications, an undesired level of crosstalk where light from one LED chip excites the phosphors and/or epitaxial layers on a neighboring LED chip. The present disclosure describes LED components with recessed cavities on a substrate, where the LED chips can be placed in the cavities, enabling the sidewalls of the cavities to prevent cross-talk between the LED chips in the LED matrix. The recessed cavities in the substrate can be used for flip-chip mounted chips or LED chips with vertical geometry. Additionally, an LED matrix can have recesses with varying depths to enable customized emission patterns.

In one aspect, an LED component comprises a substrate with a recessed cavity and at least one through via, wherein the recessed cavity comprises a base and sidewalls. The LED component also includes an LED chip mounted on the base in the recessed cavity, wherein the sidewalls of the recessed cavity are taller than at least a portion of a light emitting portion of the LED chip. In an embodiment, the sidewalls are at least flush with the LED chip. In an embodiment, the recessed cavity comprises a reflective layer on the base and sidewalls. In an embodiment, the LED chip is flip-chip mounted, and the substrate comprises at least two through vias. In an embodiment, the LED chip is a vertical LED chip. In an embodiment, the LED component further comprises a lumiphoric layer covering a top of the LED chip, wherein a top of the lumiphoric layer is at least flush with a top of the sidewalls. In an embodiment, the LED component further comprises a cover structure over a top of the recessed cavity.

In another aspect, an LED component includes a substrate with a plurality of recessed cavities, wherein each recessed cavity of the plurality of recessed cavities comprises at least one through via, a base, and sidewalls. The LED component also includes a plurality of LED chips mounted in respective bases of each of the plurality of recessed cavities, wherein the sidewalls of the plurality of recessed cavities are taller than at least a portion of a light emitting portion of the LED chips. In an embodiment, sidewalls of different recessed cavities of the plurality of recessed cavities have different heights. In an embodiment, a distribution pattern of the different recessed cavities with different heights is selected based on a far field emission pattern. In an embodiment, another plurality of LED chips can be mounted in a respective recessed cavity. In an embodiment, each LED chip of the other plurality of LED chips can emit light at respective wavelengths. In an embodiment, the LED component further comprises a plurality of field effect transistor switches mounted on a side of the substrate opposite the LED chips that can individually control the plurality of LED chips. In an embodiment, the sidewalls of the plurality of recessed cavities are at least flush with the plurality of LED chips. In an embodiment the plurality of recessed cavities comprise a reflective layer on the bases and sidewalls. In an embodiment, one or more LED chips of the plurality of LED chips are flip-chip mounted, and the substrate comprises at least two through vias per recessed cavity. In an embodiment one or more LED chips of the plurality of LED chips are vertical LED chips. In an embodiment, the LED component further includes lumiphoric layers covering a top of the plurality of LED chip, wherein a top of the lumiphoric layers are at least flush with a top of the sidewalls. In an embodiment, the LED component includes a cover structure over a top of the plurality of recessed cavities.

In another aspect, a method of fabricating an LED component includes etching a substrate to form a plurality of recessed cavities wherein each recessed cavity of the plurality of recessed cavities comprises at least one through via, a base, and sidewalls. The method also includes mounting, in respective bases of each of the plurality of recessed cavities, a plurality of LED chips wherein the sidewalls of the plurality of recessed cavities are taller than at least a portion of a light emitting portion of the LED chips.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a cross-sectional view of a light-emitting diode (LED) component with a recessed cavity in a substrate according to principles of the disclosure.

FIG. 2 is a cross-sectional view of a plurality of recessed cavities in a substrate, each with respective LED chips therein according to principles of the disclosure.

FIG. 3 is a cross-sectional view of an LED component with a recessed cavity in a substrate for a vertical geometry LED chip according to principles of the disclosure.

FIG. 4 is a cross-sectional view of an LED component with a recessed cavity in a substrate with a reflective layer according to principles of the disclosure.

FIG. 5A is a cross-sectional view of an LED component with a partial depth recessed cavity according to principles of the disclosure.

FIG. 5B is a cross-sectional view of a plurality of recessed cavities in a substrate, each with different depths according to principles of the disclosure.

FIG. 6A is a cross-sectional view of a plurality of recessed cavities in a substrate, each with respective LED chips controlled via multiplexing according to principles of the disclosure.

FIG. 6B is a cross-sectional view of a plurality of recessed cavities in a substrate, each with respective LED chips controlled via field effect transistors on a backside of the substrate according to principles of the disclosure.

FIG. 7 is a cross-sectional view of a recessed cavities with a plurality of LED chips in each cavity according to principles of the disclosure.

FIG. 8 is a cross-sectional view of a plurality of recessed cavities in a substrate, each with a lumiphoric layer according to principles of the disclosure.

FIG. 9 is a cross-sectional view of a plurality of recessed cavities in a substrate, with a flat lens covering the LED component according to principles of the disclosure.

FIG. 10 is a cross-sectional view of a plurality of recessed cavities in a substrate, with a curved cover structure covering the LED component according to principles of the disclosure.

FIG. 11 is a flow chart of a method for fabricating an LED component with recessed cavities in a substrate according to principles of the disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to light-emitting diode (LED) components, and more particularly to substrates for LED matrices that have recessed cavities. LED matrix applications involve an array of LEDs closely spaced together, resulting in conventional applications, an undesired level of crosstalk where light from one LED chip excites the phosphors and/or epitaxial layers on a neighboring LED chip. The present disclosure describes LED components with recessed cavities on a substrate, where the LED chips can be placed in the cavities, enabling the sidewalls of the cavities to prevent cross-talk between the LED chips in the LED matrix. The recessed cavities in the substrate can be used for flip-chip mounted chips or LED chips with vertical geometry. Additionally, an LED matrix can have recesses with varying depths to enable customized emission patterns.

Before delving into specific details for aspects of the present disclosure, an overview of various elements that may be included in exemplary LED packages is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure may comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements. The active layer may comprise a single quantum well, a multiple quantum well, a double heterostructure, and/or super lattice structures.

The active LED structure may be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). Other material systems include organic semiconductor materials, and other Group III-V systems such as gallium phosphide (GaP), gallium arsenide (GaAs), and related compounds. The active LED structure may be grown on a growth substrate that can include many materials, such as sapphire, silicon carbide (SiC), silicon, aluminum nitride (AlN), and GaN.

Different embodiments of the active LED structure may emit different wavelengths of light depending on the composition of the active layer. In some embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 700 nm. In certain embodiments, the active LED structure may be configured to emit light that is outside the visible spectrum, including one or more portions of the ultraviolet (UV) spectrum (e.g., 100 nm to 400 nm), or one or more portions of the near infrared spectrum, and/or the infrared spectrum (e.g., 700 nm to 1000 nm).

An LED chip can also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphor receiving at least a portion of the light generated by the LED source may re-emit light having a different peak wavelength than the LED source. An LED source and one or more lumiphoric materials may be selected such that their combined output results in light with one or more desired characteristics such as color, color point, intensity, etc.

Lumiphoric materials as described herein may be or include one or more of a phosphor, a scintillator, a lumiphoric ink, a quantum dot material, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations. In certain embodiments, lumiphoric materials may be provided over one or more surfaces of LED chips, while other surfaces of such LED chips may be devoid of lumiphoric material.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected.

The present disclosure can be useful for LED chips having a variety of geometries, such as vertical geometry or lateral geometry. A vertical geometry LED chip typically includes anode and cathode connections on opposing sides or faces of the LED chip. A lateral geometry LED chip typically includes both anode and cathode connections on the same side of the LED chip that is opposite a substrate, such as a growth substrate. In certain embodiments, a lateral geometry LED chip may be mounted on a submount of an LED package such that the anode and cathode connections are on a face of the LED chip that is opposite the submount. In this configuration, wire bonds may be used to provide electrical connections with the anode and cathode connections. In other embodiments, a lateral geometry LED chip may be flip-chip mounted on a surface of a submount of an LED package such that the anode and cathode connections are on a face of the active LED structure that is adjacent to the submount. In this configuration, electrical traces or patterns may be provided on the submount for providing electrical connections to the anode and cathode connections of the LED chip. In a flip-chip configuration, the active LED structure is configured between the substrate of the LED chip and the submount for the LED package. Accordingly, light emitted from the active LED structure may pass through the substrate in a desired emission direction. In other embodiments, an active LED structure may be bonded to a carrier submount, and the growth substrate may be removed such that light may exit the active LED structure without passing through the growth substrate.

According to aspects of the present disclosure, LED packages may include one or more elements, such as lumiphoric materials, encapsulants, light-altering materials, lenses, and electrical contacts, among others that are provided with one or more LED chips. In certain aspects, an LED package may include a support structure or support element, such as a submount.

Submount structures typically include submounts with electrically conductive traces. Exemplary submount materials include ceramic materials such as aluminum oxide or alumina, AlN, or organic insulators like polyimide (PI) and polyphthalamide (PPA). In certain embodiments, submounts may comprise a printed circuit board (PCB), sapphire, Si or any other suitable material. For PCB embodiments, different PCB types can be used such as standard FR-4 PCB, metal core PCB, or any other type of PCB. Aspects of the present disclosure are also well suited for embodiments with flexible substrates. By way of example, a flexible submount may comprise a polyimide, a polyethylene terephthalate (PET), and the like with electrically conductive traces. Flexible submounts allow improved bonding in a conformal manner to other surfaces that may not be entirely planar.

Encapsulant materials, such as silicone, epoxy, or polymethyl methacrylate (PMMA), among others, may be formed to encapsulate the LED chips over a submount. In certain embodiments, one or more lumiphoric materials, such as phosphor particles, may be integrated or otherwise embedded within the encapsulant material. Moreover, encapsulant materials may be shaped to form single lens structures and/or multiple lens structures in a single LED package.

Light-altering materials may be arranged within LED packages, such as along submount surfaces, to reflect or otherwise redirect light from the one or more LED chips in a desired emission direction or pattern. As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, scatter, or otherwise redirect light. For light-reflective materials, the light-altering material may include at least one of fused silica, fumed silica, titanium dioxide (TiO2), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque color, such as black or gray for absorbing light and increasing contrast. In certain embodiments, the light-altering material includes both light-reflective material and light-absorbing material suspended in a binder.

Aspects of the present disclosure relate to LED components where the substrates on which the LED chips are placed have recessed cavities, within which the LED chips are attached. By placing the LED chips within the recessed cavities, cross-talk, where light from one LED illuminates the lumiphoric material of another LED chip, and interference is reduced, thus improving contrast. This disclosure can be used in LED matrices, where many LED chips are in close proximity to each other, and indeed, the pitch, or distance between LED chips is very close, often between several hundred to several tens of microns. Some of the applications in which the techniques disclosed herein would be useful include LED matrixes, adaptive LED headlights, emergency and vehicle signage applications, and signal projections.

Current techniques of preventing cross-talk include backfilling light-blocking or contrast-enhancing material between the LED chips that are mounted on a flat surface of a substrate, but this can be difficult to perform, and the material doesn't always fill the gaps evenly. The techniques disclosed herein provide for an improved LED component, and improved method of fabrication, where the recessed cavities are etched into a surface of a substrate, and then the LED chips are mounted within the cavities, and the cavity sidewalls provide the light blocking between neighboring LED chips. As used here, the substrate may comprise many different materials, such as silicon, ceramics such as Al₂O₃ or aluminum nitride (AlN), glass, and FR-4. In various embodiments, the substrate could include dark or black light-altering materials for reduced cross-talk and improved contrast, or could also include light-reflective particles for increased reflectivity and reduced cross-talk. In multiple LED chip embodiments, the substrate may form a monolithic substrate with multiple cavities arranged to house multiple LED chips.

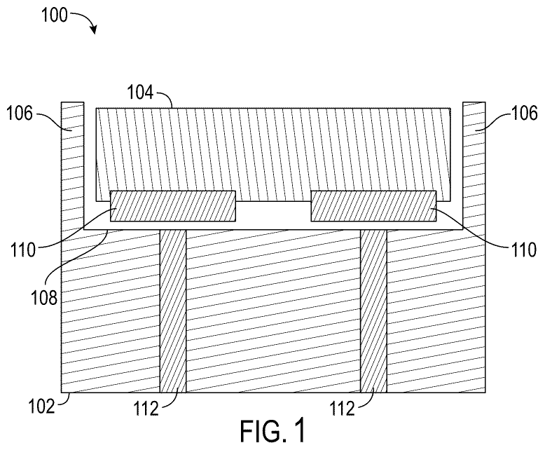

FIG. 1 is a cross-sectional view of a light-emitting diode (LED) component 100 with a recessed cavity in a substrate 102 according to principles of the disclosure.

The LED component 100 includes a recessed cavity that has side walls 106 and a base 108 on which an LED chip 104 can be mounted. Electrodes 110 of the LED chip 104 can make electric contact with through vias 112.

The side walls 106 can block light emitted by the LED chip 104 and thus prevent cross-talk with neighboring LED chips. Likewise, the side walls 106 can block or reduce light emitted by the neighboring LED chips from exciting or illuminating lumiphoric material on LED chip 104. The side walls 106 shown in FIG. 1 have vertical side walls, but in other embodiments, the side walls 106 can be sloped or curved for improved light extraction out of the cavity, reducing the number of reflections before the light exits the cavity.

The recessed cavity can be formed by etching of the substrate 102, where the etching could include chemical etching (reactive ion etching, inductively coupled plasma etching), laser etching, sandblasting, or CO₂ blasting. The through vias can also be formed by similar etching techniques.

The base 108 can be formed at a depth such that at least a portion of the light emitting portion of the LED chip 104 is below a top surface of the side walls 106. For example, in the embodiment shown in FIG. 1, the top of the LED chip 104 is flush with the top of the side wall 106. In other embodiments, the LED chip 104 can be higher than the top of the side wall 106, and in other embodiments, the side walls 106 can be higher than the top of the LED chip 104. In other embodiments, the side walls 106 can be of different heights.

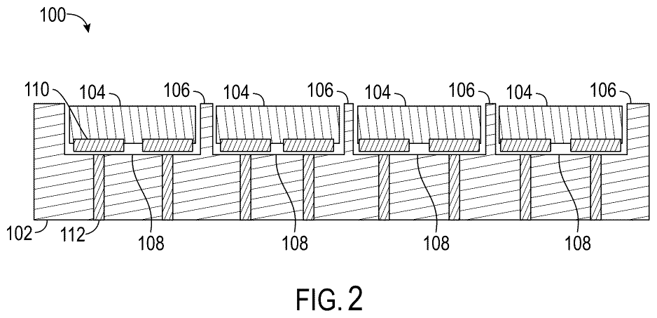

FIG. 2 is a cross-sectional view of a plurality of recessed cavities in a substrate, each with respective LED chips therein according to principles of the disclosure.

In the embodiment shown in FIG. 2, there are a plurality of LED chips 104, each in respective recessed cavities in the substrate 102. The LED chips 104 can be at the same or similar depths in the substrate 102, where the tops of the side walls 106 are at similar heights relative to the tops of the LED chips 104. While the embodiment shown in FIG. 2 is a cross-sectional view, it is to be appreciated that the array of LED chips could be planar, with neighboring LED chips in two axes.

In an embodiment, the side walls 106 can have a height between 20 μm to 500 μm, and a width of the side walls 106 between the recessed cavities can be between 5 μm to 500 μm.

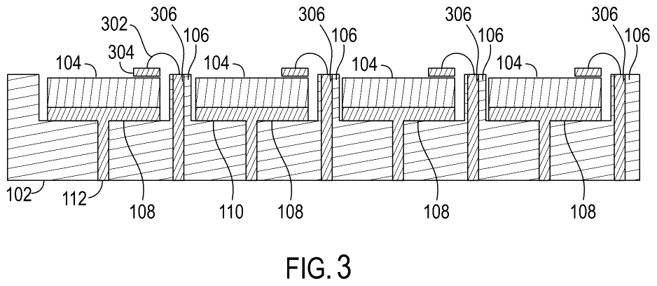

FIG. 3 is a cross-sectional view of an LED component with a recessed cavity in a substrate for a vertical geometry LED chip according to principles of the disclosure.

The embodiment in FIG. 3 is similar to the embodiment in FIG. 2, except that instead of being lateral geometry, flip-chip mounted LED chips, the LED chips 104 are vertical geometry LED chips, where the anode and cathodes are on opposing sides of the LED chip. For example, in FIG. 3, electrode 108 could be an anode, whilst electrode 304 is a cathode (or vice versa). For electrode 304, the electrical connection can be made via a wire 302 that is connected to another through via 306 through the side wall 106.

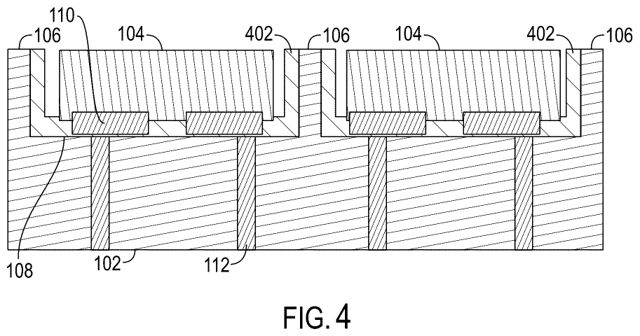

FIG. 4 is a cross-sectional view of an LED component with a recessed cavity in a substrate with a reflective layer according to principles of the disclosure.

In the embodiment in FIG. 4, the recessed cavity of the substrate 102 can include a reflective layer 402 on the base 108 and or side walls 106 of the recessed cavities. The light emitted by the LED chips 104 can reflect off the reflective layer 402, thus improving the light extraction of the LED component 100. The reflective layer 402 can increase the brightness of the LED component 100 relative to their not being a reflective layer 402, which is especially true when the substrate 102 is not particularly reflective.

In an embodiment, the reflective layer 402 could comprise a reflective amorphous dielectric (e.g., TIO₂, Al₂O₃). The reflective layer 402 could also be a distributed Bragg reflector formed from multiple layers of alternating materials with different refractive index, or by periodic variation of some characteristic (such as height) of a dielectric waveguide, resulting in periodic variation in the effective refractive index in the guide. Each layer boundary causes a partial reflection and refraction of an optical wave. In another embodiment, the reflective layer 402 could be a metallic mirror.

In various embodiments, the reflective layer 402 may only be on the base 108 of the recessed cavity, or alternatively on one or more of the side walls 106 and not the base 108, or any variation thereof depending on the desired emission profile and characteristics.

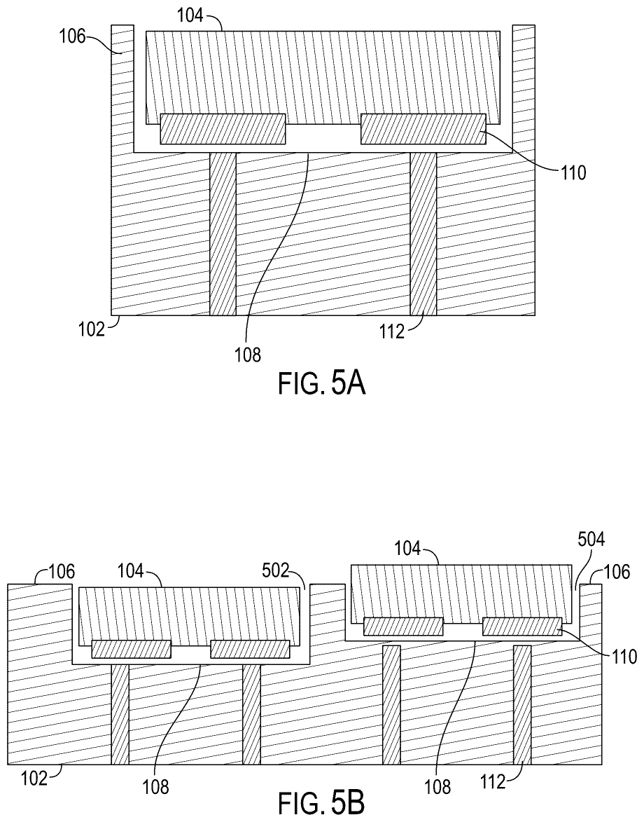

FIG. 5A is a cross-sectional view of an LED component with a partial depth recessed cavity according to principles of the disclosure.

In FIG. 5A, the base 108 of the substrate 102 is less deep relative to the side walls 106 than in the embodiments shown in FIG. 1, and the top of the LED chip 104 is above the top of the side wall 106, so that only a portion of the light emitting portion of the LED chip 104 is within the recessed cavity. In this embodiment, there may be more cross-talk than in the embodiment in FIG. 1, but depending on the desired emission profile or characteristics, this could be desirable. The depth of the recessed cavity can vary, as long as least a portion of the light emitting portion of the LED chip 104 is beneath the tops of the side walls 106.

FIG. 5B is a cross-sectional view of a plurality of recessed cavities in a substrate, each with different depths according to principles of the disclosure. In this embodiment, neighboring recessed cavities in the substrate 102 can have different depths. In an array or matrix of LED chips, the varying depths of the recessed cavities can cause different far field emission patterns, creating a light pipe. The patterns of differing depths of the recessed cavities can also facilitate and change the coupling of the light emission into a secondary optic.

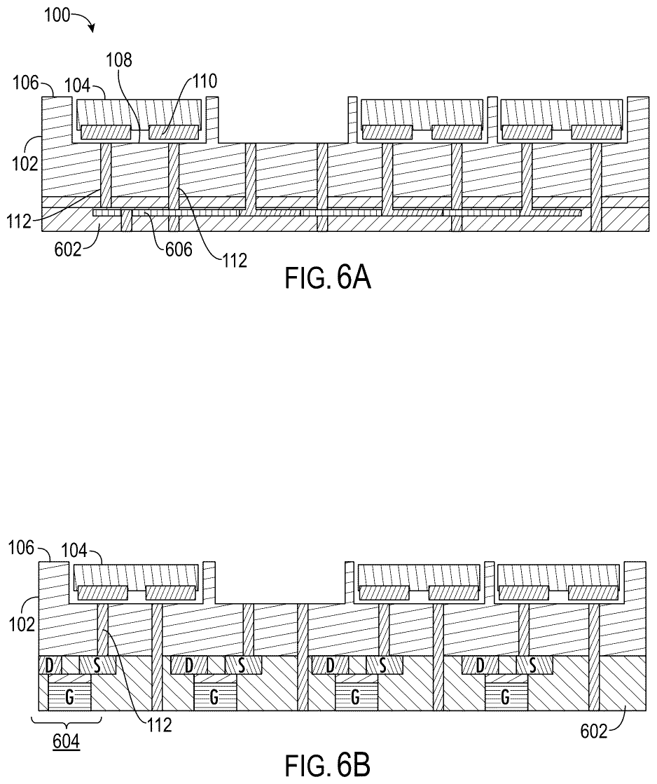

FIG. 6A is a cross-sectional view of a plurality of recessed cavities in a substrate, each with respective LED chips controlled via multiplexing according to principles of the disclosure.

In an embodiment, circuitry 606 can be included in the substrate 102 to enable sets (e.g., individual, and/or rows or columns) of the LED chips 104 to be activated and controlled via multiplexing. The circuitry 606 can be embedded in an additional layer 602 on the back side of the substrate 102, and the circuitry 606 can be electrically coupled to the through vias 112. In certain embodiments, the circuitry 606 may embody electrically conductive traces or bus lines. For example, the circuitry 606 may form part of a common anode connection or a common cathode connection for groupings of LED chips 104.

FIG. 6B is a cross-sectional view of a plurality of recessed cavities in a substrate, each with respective LED chips controlled via field effect transistors on a backside of the substrate according to principles of the disclosure.

Similar to the embodiment in FIG. 6A, the embodiment in FIG. 6B can enable individual or plural control of the LED chips 104 but in the embodiment in FIG. 6B, the control is provided by sets of field effect transistors (FET) 604. The through vias 112 can be electrically coupled to the source of the FET 604.

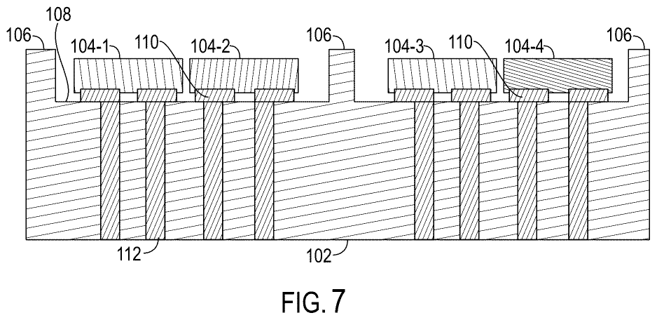

FIG. 7 is a cross-sectional view of a recessed cavities with a plurality of LED chips in each cavity according to principles of the disclosure. In the embodiment in FIG. 7, each recessed cavity of the substrate can include 2 or more LED chips 104. The LED chips 104 in each recessed cavity can be the same color or brightness or can be different colors and/or brightnesses. For example, LED chips 104-1 and 104-3 could be blue, while LED chips 104-2 and 104-4 could be red. The LED chips 104 in each individual recessed cavity can be individually controlled. In an embodiment, there could be three LED chips 104 in each recessed cavity, a green, a red, and a blue LED, where each recessed cavity and grouping of 3 LED chips is a pixel in an array of LEDs.

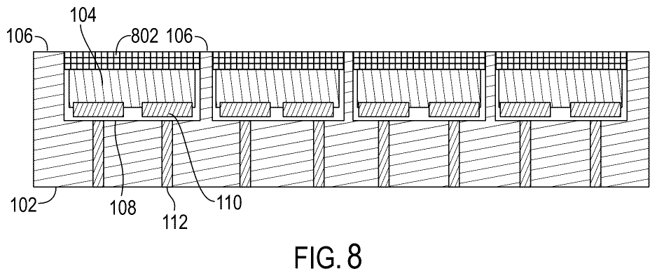

FIG. 8 is a cross-sectional view of a plurality of recessed cavities in a substrate 102, each with a lumiphoric layer 802 according to principles of the disclosure. The lumiphoric layer 802 could for example be phosphor and serve as a conversion layer where the concentration of phosphor can be configured to enable the LED component 100 to emit light at a desired color point. The lumiphoric layer 802 could, for example, cover each individual LED chip 104 and recessed cavity, or could be a continuous layer over the top of the LED chips 104 and side walls 106, which would be easier to fabricate but would reduce contrast. In other embodiments, the lumiphoric layer 802 may reside entirely within the cavities for reduced contrast between wavelength-converted emissions.

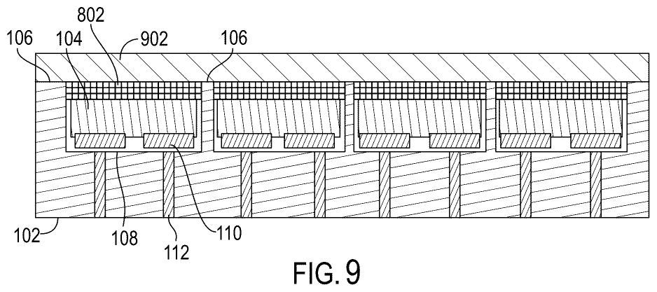

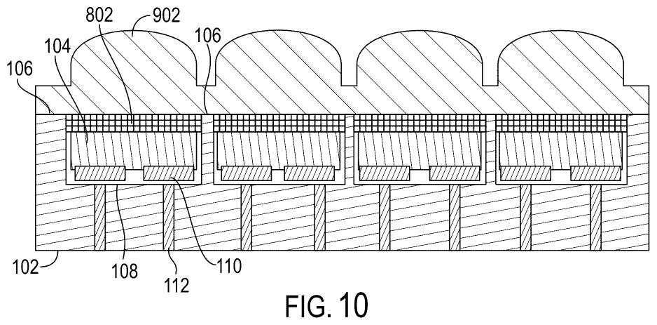

In the embodiments in FIGS. 9 and 10, there can be a cover structure 902 that could cover the LED chips 104 and lumiphoric layer 802. The cover structure could be a transparent plastic or other material that provides protection to the LED chips 104 or could be a lens to help configure the far field emission pattern of the LED array. In an embodiment shown in FIG. 9 the cover structure could be a flat lens, whereas in FIG. 10, the cover structure could be a curved lens with one or more optical elements per LED chip 104.

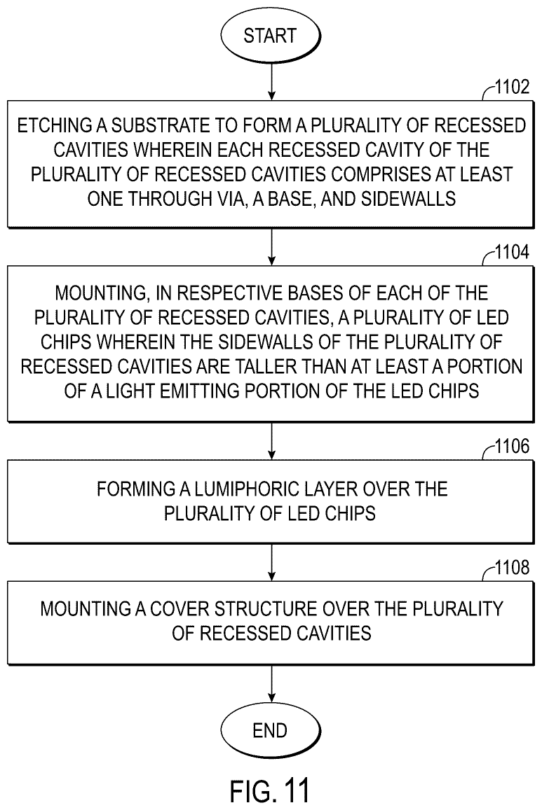

FIG. 11 is a flow chart of a method for fabricating an LED component with recessed cavities in a substrate according to principles of the disclosure.

The method can begin at step 1102 where the method includes etching a substrate to form a plurality of recessed cavities wherein each recessed cavity of the plurality of recessed cavities comprises at least one through via, a base, and sidewalls. The etching could include chemical etching (reactive ion etching, inductively coupled plasma etching), laser etching, sandblasting, or CO₂ blasting. The through vias can also be formed by similar etching techniques. The etching could be performed until the base of the recessed cavity is at a depth such that at least a portion of the light emitting portion of the LED chip is below a top surface of the side walls of the recessed cavity.

In an embodiment, a layer can be added or deposited over the substrate initially, where the layer could be a metal or a ceramic layer, and then at step 1102, the additional layer over the substrate can be etched to form the recessed cavities. In an embodiment, the layer could first be formed, and then bonded to the substrate with an adhesive material.

In an embodiment, the layer could include Al₂O_{3,} aluminum nitride (AlN), glass, or silicon, and the cavities could be isolated from the sidewalls using a mask (hard mask or photolithography) and the cavities could be etched away, leaving the side walls.

In another embodiment, a seed layer could be deposited, and a region defined for electroplating via photolithography and the side walls could be electroplated. The copper electroplated sidewalls can be coated with silver, electroless nickel immersion gold (ENIG), or Electroless nickel immersion gold (ENEPIG).

At 1104, the method includes mounting, in respective bases of each of the plurality of recessed cavities, a plurality of LED chips wherein the sidewalls of the plurality of recessed cavities are taller than at least a portion of a light emitting portion of the LED chips. In the case of flip-chip mounted LED chips, the electrodes of the LED chips could be soldered to the electrical pads connected to the through vias in the substrate. In the case of vertical geometry LEDs, one of the electrodes could be soldered to the through via, and a wire bond formed to the top electrode.

At 1106, the method includes forming a lumiphoric layer over the plurality of LED chips. The lumiphoric layer could for example be phosphor and serve as a conversion layer where the concentration of phosphor can be configured to enable the LED component to emit light at a desired color point. The lumiphoric layer could for example cover each individual LED chip and recessed cavity, or could be a continuous layer over the top of the LED chips and side walls, which would be easier to fabricate but would reduce contrast.

At 1108, the method includes mounting a cover structure over the plurality of recessed cavities and LED chips. The cover structure could be a transparent plastic or other material that provides protection to the LED chips or could be a lens to help configure the far field emission pattern of the LED array. In an embodiment, the cover structure could be a flat lens, whereas in other embodiments the cover structure could be a curved lens with one or more optical elements per LED chip.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) component, comprising:
a substrate comprising a recessed cavity and at least one through via, wherein the recessed cavity comprises a base and sidewalls;
an LED chip mounted on the base in the recessed cavity, wherein the sidewalls of the recessed cavity are taller than at least a portion of a light emitting portion of the LED chip.

2. The LED component of claim 1, wherein the sidewalls are at least flush with the LED chip.

3. The LED component of claim 1, wherein the recessed cavity comprises a reflective layer on the base and sidewalls.

4. The LED component of claim 1, wherein the LED chip is flip-chip mounted, and the substrate comprises at least two through vias.

5. The LED component of claim 1, wherein the LED chip is a vertical LED chip.

6. The LED component of claim 1, further comprising a lumiphoric layer covering a top of the LED chip, wherein a top of the lumiphoric layer is at least flush with a top of the sidewalls.

7. The LED component of claim 1, further comprising a cover structure over a top of the recessed cavity.

8. A light-emitting diode (LED) component, comprising:
a substrate with a plurality of recessed cavities, wherein each recessed cavity of the plurality of recessed cavities comprises at least one through via, a base, and sidewalls; and
a plurality of LED chips mounted in respective bases of each of the plurality of recessed cavities, wherein the sidewalls of the plurality of recessed cavities are taller than at least a portion of a light emitting portion of the LED chips.

9. The LED component of claim 8, wherein sidewalls of different recessed cavities of the plurality of recessed cavities have different heights.

10. The LED component of claim 9, wherein a distribution pattern of the different recessed cavities with different heights is selected based on a far field emission pattern.

11. The LED component of claim 8, wherein another plurality of LED chips can be mounted in a respective recessed cavity.

12. The LED component of claim 11, wherein each LED chip of the other plurality of LED chips can emit light at respective wavelengths.

13. The LED component of claim 8, further comprising a plurality of field effect transistor switches mounted on a side of the substrate opposite the LED chips that can individually control the plurality of LED chips.

14. The LED component of claim 8, wherein the sidewalls of the plurality of recessed cavities are at least flush with the plurality of LED chips.

15. The LED component of claim 8, wherein the plurality of recessed cavities comprise a reflective layer on the bases and sidewalls.

16. The LED component of claim 8, wherein one or more LED chips of the plurality of LED chips are flip-chip mounted, and the substrate comprises at least two through vias per recessed cavity.

17. The LED component of claim 8, wherein one or more LED chips of the plurality of LED chips are vertical LED chips.

18. The LED component of claim 8, further comprising lumiphoric layers covering a top of the plurality of LED chips, wherein a top of the lumiphoric layers are at least flush with a top of the sidewalls.

19. The LED component of claim 8, further comprising a cover structure over a top of the plurality of recessed cavities.

20. A method for fabricating a light-emitting diode (LED) component, comprising:
etching a substrate to form a plurality of recessed cavities wherein each recessed cavity of the plurality of recessed cavities comprises at least one through via, a base, and sidewalls; and
mounting, in respective bases of each of the plurality of recessed cavities, a plurality of LED chips wherein the sidewalls of the plurality of recessed cavities are taller than at least a portion of a light emitting portion of the LED chips.
